(19) United States
(12) Patent Application Publication
(10) Pub. No.: US 2017/0271173 A1
(43) Pub. Date: Sep. 21, 2017

(54) METHOD FOR FORMING METALLIZATION STRUCTURE

(71) Applicant: Winbond Electronics Corp., Taichung City (TW)

(72) Inventor: Yu-Hsuan HO, Taoyuan City (TW)

(21) Appl. No.: 15/259,504

(22) Filed: Sep. 8, 2016

(30) Foreign Application Priority Data
Mar. 16, 2016 (CN) 201610149306.2

(51) Int. Cl. H01L 21/48; B22F 7/00; C23C 8/12; B33Y 10/00; B33Y 80/00; C23C 8/14; B22F 3/105; B22F 7/04

(52) U.S. Cl. CPC H01L 21/4857; B22F 3/1055; B22F 7/008; B22F 7/04; B33Y 10/00; B33Y 80/00; C23C 8/14; C23C 8/12; H01L 21/4803; B22F 2007/042; B22F 2201/03; B22F 2201/10; B22F 2201/20; B22F 2302/45; B22F 2301/052; B22F 2301/10; B22F 2301/205; B22F 2301/20; B22F 2301/35; B22F 2998/10

(57) ABSTRACT

A method for forming a metallization structure is provided, including forming a metallic powder layer on a substrate; performing a first laser sintering on a first portion of the metallic powder layer to form a metal layer; and in the presence of oxygen, performing a second laser sintering on a second portion of the metallic powder layer to form a metal oxide layer to serve as a first dielectric layer.

### CROSS REFERENCE TO RELATED APPLICATIONS

This application claims priority of China Patent Application No. 201610149306.2, filed on Mar. 16, 2016, the entirety of which is incorporated by reference herein.

### TECHNICAL FIELD

The present disclosure relates to a 3D-printing technology, and in particular it relates to a method for forming a metallization structure.

### BACKGROUND

In recent years, 3D-printing technology has attracted attention in design and manufacturing industries because of its low-cost and easy-to-use processes. Among 3D-printing technology, selective laser sintering (SLS) is a highly reliable and intensive process in current printing technology. Laser sintering refers to the process by which scattered metallic powders are fused to form a solid mass with good mechanical strength through the application of a high-power laser.

However, since metal-based materials used in selective laser sintering only have conductive properties, but are lacking in dielectric properties, the prospects for applying this process to the semiconductor industry are limited.

### BRIEF SUMMARY OF THE INVENTION

An embodiment of the present invention provides a method for forming a metallization structure, comprising: providing a substrate; forming a metallic powder layer on the substrate; performing a first laser sintering on a first portion of the metallic powder layer to form a metal layer; and in the presence of oxygen, performing a second laser sintering on a second portion of the metallic powder layer to form a metal oxide layer to serve as a first dielectric layer.

Another embodiment of the present invention provides a method for forming a metallization structure, comprising: providing a package on a substrate; forming a metallic powder layer on the substrate; performing a first laser sintering on a first portion of the metallic powder layer to form a first metal layer; in the presence of oxygen, performing a second laser sintering on a second portion of the metallic powder layer to form a metal oxide layer to serve as a first dielectric layer; and repeating the steps of forming the metallic powder layer, the first laser sintering and the second laser sintering on the metal layer and the first dielectric layer to form a plurality of metal layers and a plurality of first dielectric layers, wherein the plurality of metal layers and the plurality of first dielectric layers serve as a first metallization structure.

In summary, a metal oxide layer is formed as a dielectric layer by laser sintering a metallic powder layer in the presence of oxygen. As such, metal layers and metal oxide layers can be formed by sequential laser sintering to provide metallization structures for semiconductor devices.

### BRIEF DESCRIPTION OF THE DRAWINGS

The present invention can be more fully understood by reading the subsequent detailed description and examples with references made to the accompanying drawings, wherein:

FIG. 1 illustrates a flow chart of some embodiments of a method for forming a metallization structure according to the present disclosure;

FIG. 2A-2E illustrates a schematic view of the first embodiment of a method for forming a metallization structure according to the present disclosure;

FIG. 3A-3C illustrates a schematic view of the second embodiment of a method for forming a metallization structure according to the present disclosure; and

FIG. 4A-4C illustrates a schematic view of the third embodiment of a method for forming a metallization structure according to the present disclosure.

### DETAILED DESCRIPTION OF THE INVENTION

The following preferred embodiments are made for the purpose of making above-mentioned and other purposes, features and advantages of the present disclosure more obviously. The following provides detailed description with references made to the accompanying drawings.

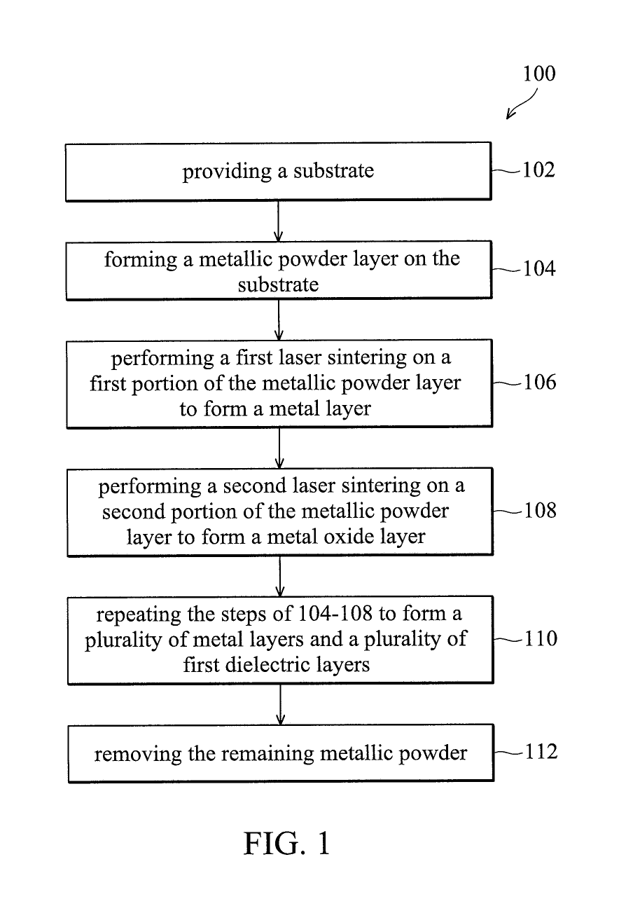

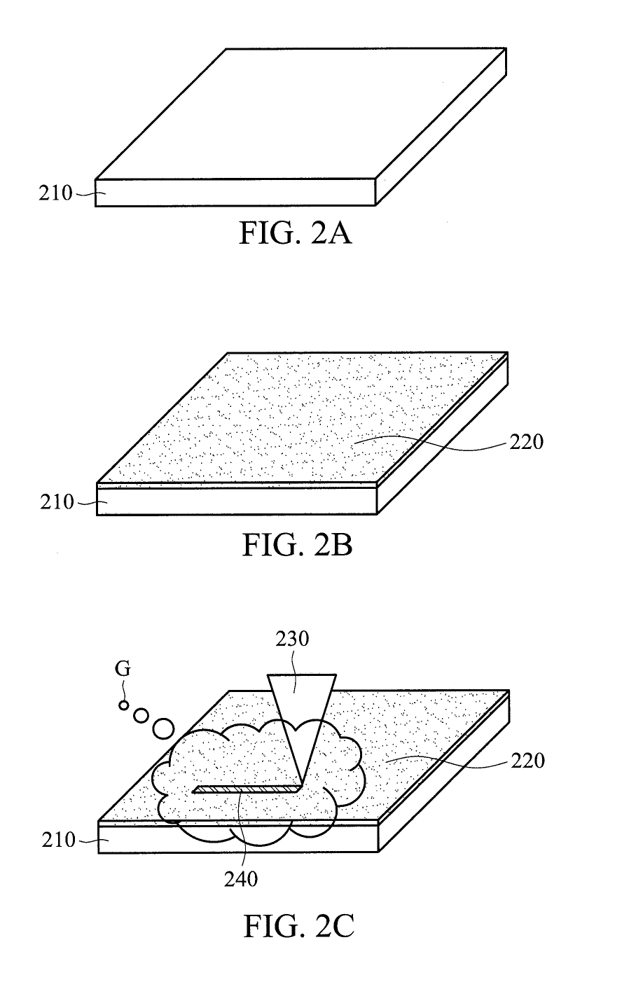

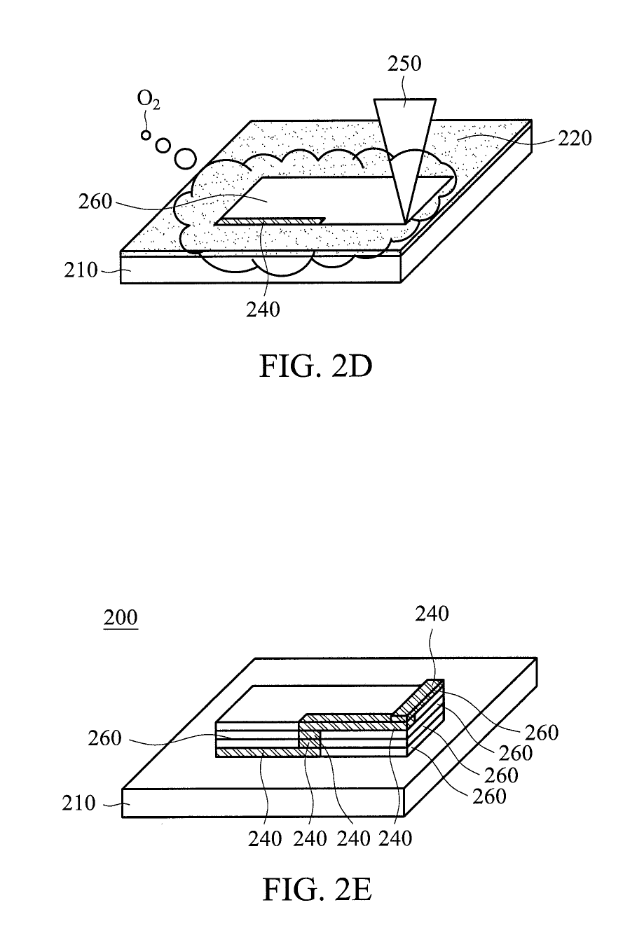

FIG. 1 illustrates a flow chart of embodiments of the method 100 for forming a metallization structure according to the present disclosure. FIG. 2A-2E illustrates a schematic view of a first embodiment of a method for forming the metallization structure 200 according to the present disclosure.

Referring to FIG. 1 and FIG. 2A, a substrate 210 is provided in a chamber (not shown) (step 102). In some embodiments, the substrate 210 may be a semiconductor wafer, a die, a package or a printed circuit board (PCB). In some embodiments, the substrate 210 may include an elementary semiconductor, a compound semiconductor and/or an alloy semiconductor. Examples of elementary semiconductors include monocrystalline silicon, polycrystalline silicon, amorphous silicon, germanium and diamond. Examples of compound semiconductors include silicon carbide, gallium arsenic, indium phosphide, indium arsenide and indium antimonide. Examples of alloy semiconductors include silicon germanium, silicon germanium carbide, gallium arsenic phosphide and gallium indium phosphide. In some embodiments, the substrate 210 may include various rigid supporting substrates, such as metal, glass, ceramics, polymeric materials or combinations thereof. In some embodiments, the chamber is controlled under a low vacuum, e.g., from about 10⁻³ mbar to about 10⁻⁵ mbar.

Referring to FIG. 1 and FIG. 2B, a metallic powder layer 220 is then formed on the substrate 210 (step 104). In some embodiments, the metallic powder layer 220 may include Cu, Al, Cr, Mo, Ti, Fe, stainless steel, Co—Cr alloy, wrought steel, Ti-6Al-4V alloy or other metal materials. In some embodiments, the thickness of the metallic powder layer is in a range from about 1 μm to about 500 μm, e.g., about 250 μm. If the metallic powder layer is too thick (more than 500 μm), the metallic powder layer may be incompletely sintered; on the other hand, if the metallic powder layer is too thin (less than 1 μm), the substrate may be damaged by sintering.

Referring to FIG. 1 and FIG. 2C, a high concentration of inert gas G (e.g. nitrogen, argon) is provided around a first portion of the metallic powder layer 220, and a laser sintering is then performed at the first portion of the metallic powder layer 220 by moving a laser source 230 to form a metal layer 240 (step 106). Furthermore, the first portion of the metallic powder layer 220 may be formed into the metal layer 240 with different shapes according to the design requirements. In some embodiments, the chamber may contain at least 90% inert gas G (e.g. nitrogen, argon). In some embodiments, the laser source 230 may be Yb optical fiber laser, CO₂ infrared laser or electron beam, the power of the laser source 230 may be in a range from about 50 W to about 5000 W, e.g. the power of Yb optical fiber laser may be 400 W. If the power of the laser source 230 is too high (more than 5000 W), the substrate may be damaged by sintering. If the power of the laser source 230 is too low (less than 50 W), the metallic powder layer may be incompletely sintered.

Referring to FIG. 1 and FIG. 2D, a high concentration of oxygen is provided around a second portion of the metallic powder layer 220, and a laser sintering is then performed at the second portion of the metallic powder layer 220 by moving a laser source 250 to form a metal oxide layer 260 (step 108). In some embodiments, the metal layer 240 is surrounded by the second portion of the metallic powder layer 220, such that the metal layer 240 is electrically isolated from other components by the metal oxide layer 260. In some embodiments, the chamber may contain at least 90% oxygen. In some embodiments, the laser source 250 may be Yb optical fiber laser, CO₂ infrared laser or electron beam, and the power of the laser source 250 may be in a range from about 50 W to about 5000 W, e.g. the power of Yb optical fiber laser may be 400 W. In some embodiments, the dielectric coefficient (∈ᵣ) of the metal oxide layer 260 may be in a range from about 3 to about 200.

Referring to FIG. 1 and FIG. 2E, the steps of forming the metallic powder layer 220, the first laser sintering and the second laser sintering in FIG. 2B-2D are repeated on the metal layer 240 and the metal oxide layer 260. As such, a multilayer metallization structure 200 with a plurality of metal layers 240 and a plurality of metal oxide layers 260 can be fabricated in a vertically-additive, layer-by-layer fashion. In some embodiments, the plurality of metal layers 240 are electrically connected to each other. Furthermore, shapes of each metal layer 240 are not limited to linear or bulk patterns, but may vary depending on design requirements. In addition, it should be noted that since both the metal layer 240 and the metal oxide layer 260 are sintered from the metallic powder layer 220, both of them have the same metal elements.

Finally, unsintered portions of the metallic powder layer 220 are removed after the first and second laser sintering (step 112). For example, in some embodiments, the remaining metallic powder may be removed using compressed air. It should be noted that all of the unsintered portions of the metallic powder layer 220 may be removed after repeating all the steps of the first and second laser sintering; alternatively, unsintered portions of the metallic powder layer 220 may also be removed every time after the first and second sintering.

While in the above method, the first laser sintering in the absence of oxygen is performed prior to the second laser sintering in the presence of oxygen, it should be understood that the first laser sintering may also be performed after the second laser sintering. Additionally, in the embodiments of the present invention, when repeating the first and second laser sintering alternatively, the high concentration of gas may be provided merely around the sites of the sintering, which would eliminate the need to replace the gas in the entire chamber. For example, a high concentration of inert gas G (e.g. nitrogen, argon) may be provided around the sites of the first laser sintering, and a high concentration of oxygen may be provided around the sites of the second laser sintering. As a result, the time required for forming the metallization structure of the present invention can be reduced substantially.

As described above, the metallization structure formed in the present invention includes a metal structure formed by connection of the plurality of metal layers 240 and a dielectric structure formed by stacking of the plurality of metal oxide layers 260. Furthermore, since the laser sintering is successively performed on the metallic powder in either the absence or presence of oxygen in the chamber, the time and cost required for forming a metallization structure in the present invention may be substantially reduced comparing to conventional deposition and photolithography processes. In addition, the metal oxide layer can be formed by performing the laser sintering on metallic powder with high concentration of oxygen, thereby overcoming the incapability of forming dielectric materials in conventional selective laser sintering technique and furthering the technique to semiconductor or other industries.

Furthermore, it should be noted that the vertical portion of conventional metallization structures must be formed by etching via holes in dielectric layers and then filling metal into the via holes. Therefore, the height of the conventional via plug is limited by the aspect ratio and metal-filling ability. However, since the metallization structure of the present invention is formed in a vertically-additive fashion, its vertical portion will not be influenced by the factors cited above, and it can be formed to the desired height.

While the disclosed methods may be illustrated and/or described herein as a series of steps, it will be understood that the illustrated ordering of such steps are not to be interpreted in a limiting sense. For example, some steps may occur in a different order and/or concurrently with other steps apart from those illustrated and/or described herein. For example, the first laser sintering may be performed before the second laser sintering, and may also be performed after the second laser sintering. For example, removing the unsintered metallic powder layer may be performed after all repeats of the first and second laser sintering, or it may also be performed every time after the first and second laser sintering. Furthermore, not all illustrated steps may be required to implement one or more aspects or embodiments of the description herein, and one or more of the steps depicted herein may be carried out in one or more separate steps and/or phases.

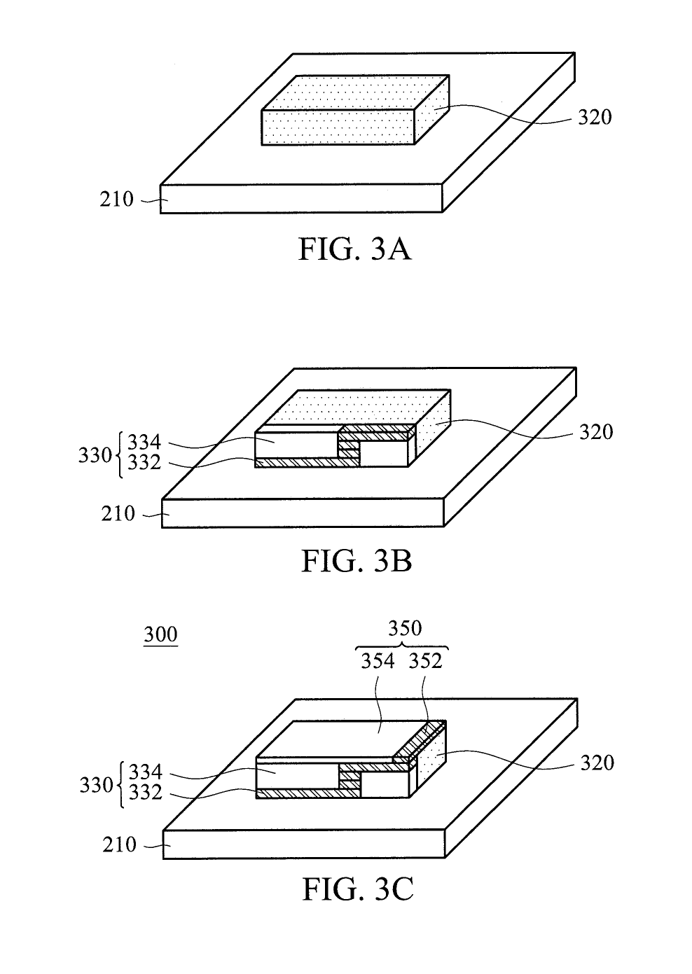

FIG. 3A-3C illustrates a schematic view of a second embodiment of a method for forming a metallization structure according to the present disclosure. In this embodiment, a dielectric structure is additionally disposed as a supporting component of a metallization structure by using deposition methods, other than sintering, thereby reducing the sintering repeats and simplifying the processes.

Referring to FIG. 3A, a dielectric structure 320 is formed on a substrate 210. The substrate 320 may include the same materials as mentioned above, and the details are not repeated herein. In some embodiments, the dielectric structure 320 may include silicon oxide, silicon nitride, silicon oxynitride or combinations thereof. In some embodiments, the dielectric structure 320 may be deposited by using a chemical vapor deposition (CVD) process, an atomic layer deposition (ALD) process, a physical vapor deposition (PVD) process, another applicable process, or a combination thereof.

Referring to FIG. 3B, a metallization structure 330 having a metal structure 332 and a dielectric structure 334 is formed along a side surface of the dielectric structure 320 by using the method 100 disclosed in FIG. 1. In some embodiments, the metal structure 332 may include Cu, Al, Cr, Mo, Ti, Fe, stainless steel, Co—Cr alloy, wrought steel, Ti-6Al-4V alloy or other metal materials. In some embodiments, the material of the dielectric structure 334 is the oxide of the metal structure 332, i.e. the metal structure 332 and the dielectric structure 334 have the same metal elements. Furthermore, each metal layer of the metal structure 332 may have various circuit patterns depending on demand.

Referring to FIG. 3C, in some embodiments, a metallization structure 350 having a metal structure 352 and a dielectric structure 354 may be formed on the dielectric structure 320 and the metallization structure 330. The metal structure 352 is electronically connected to the metal structure 332. Furthermore, the metal structure 352 may have various circuit patterns depending on demand. The metallization structure of the present embodiment is thus accomplished.

In the present embodiment, a metallization structure is made of the dielectric structure 320, the metallization structure 330 and the metallization structure 350. The dielectric structure 320 serves as a supporting component of the metallization structure 350. By additionally forming the dielectric structure 320, the metallization structure 350 can be supported without sintering a great amount of dielectric structures 334, thereby reducing the time and cost required to form the metallization structure. In addition, in some embodiments, the metallization structure 330 may be formed before forming the dielectric structure 320.

In general, in the packaging process, a plurality of different masks is typically required to fabricate various circuit patterns on the different surfaces of a package, which is complex and costly. The third embodiment of the present disclosure provides a method for forming a metallization structure that can be applied to the fabrication of circuit patterns in a simple and low-cost manner.

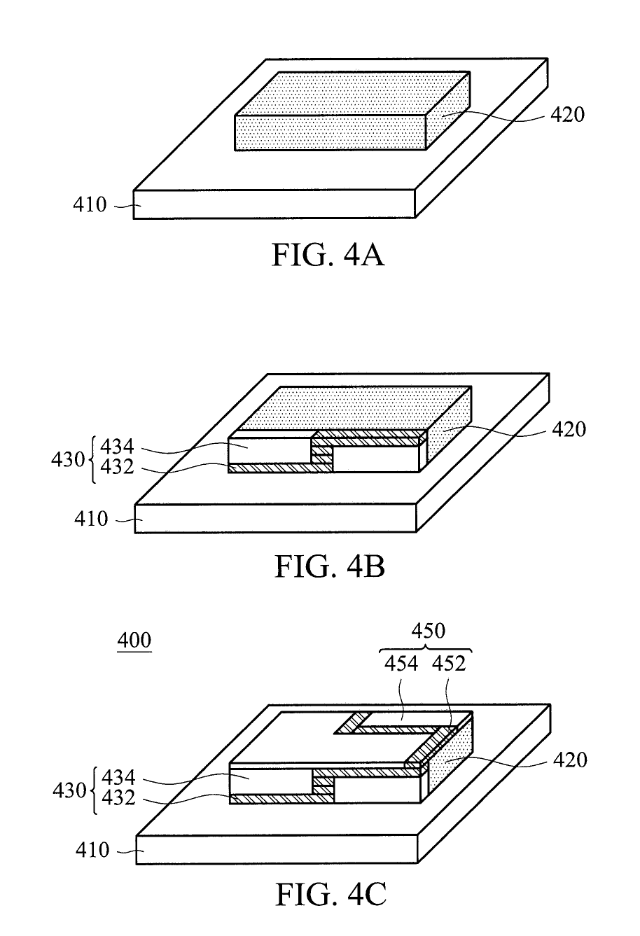

FIG. 4A-4C illustrates a schematic view of a third embodiment of a method for forming a metallization structure according to the present disclosure. In the present embodiment, the method 100 for forming a metallization structure is applied in a package 420, and the substrate described above may be regarded as a carrier for packages of various types.

Referring to FIG. 4A, a package 420 is disposed on a carrier 410. In some embodiments, the carrier 410 may include various rigid supporting substrates, such as metal, glass, ceramics, polymeric materials or combinations thereof. In some embodiments, the package 420 may include light-emitting diode (LED) packages, solar packages, micro-electro mechanical (MEM) packages or other semiconductor packages.

Referring to FIG. 4B, a metallization structure 430 having a metal structure 432 and a dielectric structure 434 is formed along a side surface of the package 420 by using the method 100 disclosed in FIG. 1. In some embodiments, the metal structure 432 may include Cu, Al, Cr, Mo, Ti, Fe, stainless steel, Co—Cr alloy, wrought steel, Ti-6Al-4V alloy or other metal materials. In some embodiments, the material of the dielectric structure 434 is the oxide of the metal structure 432, i.e. the metal structure 432 and the dielectric structure 434 have the same metal elements. Furthermore, each metal layer of the metal structure 432 may have various circuit patterns, depending on demand.

Referring to FIG. 4C, in some embodiments, a metallization structure 450 having a metal structure 452 and a dielectric structure 454 may be formed on the package 420 and the metallization structure 430. The metal structure 452 is electronically connected to the metal structure 332. Furthermore, the metal structure 452 may have various circuit patterns depending on demand.

In conventional techniques, a plurality of masks is required to fabricate circuit patterns on different surfaces of a package, which is complex and high-cost. By contrast, in the present embodiment, metal structures and/or dielectric structures can be sintered at any site of each surface of packages through the selective laser sintering technique. Furthermore, various circuit patterns can be obtained to achieve the chip-level package in a simple and low-cost manner. Additionally, since the metal structure formed by laser sintering has strong mechanical properties, the stability of the package can be increased; and since a metal oxide formed by laser sintering has better heat conductive effect than general plastics or polymeric materials, problems related to device overheating can be solved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a metallization structure, comprising:
providing a substrate;
forming a metallic powder layer on the substrate;
performing a first laser sintering on a first portion of the metallic powder layer to form a metal layer;
in presence of oxygen, performing a second laser sintering on a second portion of the metallic powder layer to form a metal oxide layer to serve as a first dielectric layer.

2. The method for forming a metallization structure as claimed in claim 1, further comprising:
repeating the steps of forming the metallic powder layer, the first laser sintering and the second laser sintering on the metal layer and the first dielectric layer to form a plurality of metal layers and a plurality of first dielectric layers.

3. The method for forming a metallization structure as claimed in claim 1, further comprising: forming a second dielectric layer on a surface of the substrate.

4. The method for forming a metallization structure as claimed in claim 3, wherein the second dielectric layer comprises silicon oxide, silicon nitride, silicon oxynitride or a combination thereof.

5. The method for forming a metallization structure as claimed in claim 1, wherein the first laser sintering and the second laser sintering are performed under a low vacuum of about 10⁻³-10⁻⁵ mbar in a chamber.

6. The method for forming a metallization structure as claimed in claim 1, wherein the first laser sintering is performed under an inert atmosphere.

7. The method for forming a metallization structure as claimed in claim 6, wherein the chamber contains at least 90 volume percent of the inert gas.

8. The method for forming a metallization structure as claimed in claim 1, wherein the substrate is a semiconductor wafer, a die, a package or a printed circuit board (PCB).

9. The method for forming a metallization structure as claimed in claim 1, wherein the metallic powder layer comprises Cu, Al, Cr, Mo, Ti, Fe, stainless steel, Co—Cr alloy, wrought steel or Ti-6Al-4V alloy.

10. The method for forming a metallization structure as claimed in claim 1, wherein the first laser sintering is performed before the second laser sintering.

11. The method for forming a metallization structure as claimed in claim 1, wherein the first laser sintering is performed after the second laser sintering.

12. A method for forming a metallization structure, comprising:
providing a package on a substrate;
forming a metallic powder layer on the substrate;
performing a first laser sintering on a first portion of the metallic powder layer to form a first metal layer;
in the presence of oxygen, performing a second laser sintering on a second portion of the metallic powder layer to form a metal oxide layer to serve as a first dielectric layer; and
repeating the steps of forming the metallic powder layer, the first laser sintering and the second laser sintering on the metal layer and the first dielectric layer to form a plurality of metal layers and a plurality of first dielectric layers,
wherein the plurality of metal layers and the plurality of first dielectric layers serve as a first metallization structure.

13. The method for forming a metallization structure as claimed in claim 12, further comprising: forming a second metallization structure on the package and the first metallization structure.

14. The method for forming a metallization structure as claimed in claim 13, wherein the second metallization structure comprises a second metal layer and a second dielectric layer.

15. The method for forming a metallization structure as claimed in claim 13, wherein the steps of forming the second metallization structure on the package comprise: performing the steps of forming the metallic powder layer, the first laser sintering, and the second laser sintering.

16. The method for forming a metallization structure as claimed in claim 12, wherein the first laser sintering and the second laser sintering are performed under a low vacuum of about 10⁻³-10⁻⁵ mbar in a chamber.

17. The method for forming a metallization structure as claimed in claim 12, wherein the first laser sintering is performed under an inert atmosphere.

18. The method for forming a metallization structure as claimed in claim 12, wherein the metallic powder layer comprises Cu, Al, Cr, Mo, Ti, Fe, stainless steel, Co—Cr alloy, wrought steel or Ti-6Al-4V alloy.

19. The method for forming a metallization structure as claimed in claim 12, wherein the first laser sintering is performed before the second laser sintering.

20. The method for forming a metallization structure as claimed in claim 12, wherein the first laser sintering is performed after the second laser sintering.
